(19) United States
(12) Patent Application Publication
(10) Pub. No.: US 2010/0230274 A1
(43) Pub. Date: Sep. 16, 2010

(54) MINIMIZING MAGNETRON SUBSTRATE INTERACTION IN LARGE AREA SPUTTER COATING EQUIPMENT

(75) Inventors: Philip A. Greene, Oakland, CA (US); Hans Peter Theodorus Ceelen, Rio Vista, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/722,116

(22) Filed: Mar. 11, 2010

Related U.S. Application Data
(60) Provisional application No. 61/159,745, filed on Mar. 12, 2009.

(51) Int. Cl. C23C 14/35

(52) U.S. Cl. 204/192.12; 204/298.16; 204/298.12

(57) ABSTRACT

A method and apparatus for performing physical vapor deposition on a large-area substrate is provided. One or more sputtering targets are disposed in a chamber, with each sputtering target comprising a magnet assembly. Each magnet assembly may comprise a plurality of magnet units aligned such that the magnetic polarity of the magnet units is complementary, and the magnetic fields of the magnet units couple. Each magnet unit thus comprises a plurality of magnets arranged such that the polarity of each magnet is opposite that of adjacent magnets in the same magnet unit. Alternately, each magnet assembly may comprise a plurality of magnets individually oriented to complement the magnetic fields of its neighbors. A substrate support having an insulating surface may also be provided.

### CROSS-REFERENCE TO RELATED APPLICATIONS

This application claims benefit of U.S. Provisional Patent Ser. No. 61/159,745, filed Mar. 12, 2009, which is incorporated herein by reference.

### FIELD

Embodiments of the invention relate to magnetic assemblies for large-area sputter coating equipment. Specifically, embodiments of the invention relate to methods of improving uniformity of deposition in large-area sputter coating equipment.

### BACKGROUND

Physical vapor deposition, or sputtering, is a commonly used process for depositing material on a substrate. The material to be deposited is contained in a target generally disposed above the substrate to be coated, all in a vacuum chamber. A gas is provided to the chamber, and an electric potential applied to ionize the gas into a plasma. The ions are accelerated toward the target by a magnetic field provided by permanent magnets disposed in a convenient relationship to the target. The ions collide with the target, dislodging particles that fall onto the substrate below.

Deposition by sputtering is generally non-uniform for a variety of reasons. Density of the plasma may be affected by geometry of the apparatus. The magnetic field may be non-uniform due to variation among the magnets or defects in the relationship of the magnets to the target. In some cases, temperature variation at different locations on the target may result in non-uniform deposition. As the dimension of devices and layers formed on substrates grows smaller with the general progression of miniaturization in the semiconductor industries, tolerance for non-uniformity diminishes as well, and other sources of non-uniformity, some of which may emanate from nature itself, must be managed. Thus, there is a continuing need for apparatus and methods for improved deposition uniformity in large-area sputtering processes.

### SUMMARY

Embodiments of the invention provide a magnetic assembly for a large-area sputtering apparatus, comprising a plurality of magnet clusters, each cluster comprising a plurality of magnet units oriented along the major axis of the cluster, each cluster adjacent to at least one other cluster, and each cluster oriented such that its magnetic field couples with the magnetic fields of adjacent clusters.

Other embodiments provide a method of forming a film on a large-area substrate by physical vapor deposition, comprising aligning a plurality of oriented magnetic clusters, each cluster having a magnetic polarity, inside one or more sputtering targets adjacent to the substrate such that the magnetic fields of the clusters couple.

Other embodiments provide an apparatus for depositing a film on a large-area substrate by physical vapor deposition, comprising a substrate support having an insulating surface and a plurality of sputtering target assemblies adjacent the substrate support, each sputtering target assembly comprising a cylinder-like target and a magnet assembly inside the cylinder-like target, wherein each magnet assembly comprises a plurality of magnet units arranged in a linear orientation along an axis of the magnet assembly, each magnet unit comprising a plurality of magnets, each magnet in a magnet unit having a magnetic polarity aligned opposite that of adjacent magnets in the magnet unit, each magnet unit having a polarity aligned opposite that of adjacent magnet units, and each magnet assembly having a polarity aligned opposite that of adjacent magnet assemblies.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a perspective view of a magnet assembly according to one embodiment of the invention.

FIG. 1B is a cross-sectional view of the magnet assembly of FIG. 1A.

FIG. 1C is a top view of the magnet assembly of FIG. 1A.

FIG. 2 is a perspective view of a large-area sputtering chamber according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The invention generally provides apparatus and methods for coating large panel substrates. A plurality of sputtering sources are arranged in a sputtering chamber above a substrate support. The sputtering sources are generally elongated cylinder-like members having magnet clusters inside. Each magnet cluster has a magnetic field that facilitates collision of ions with the sputtering source.

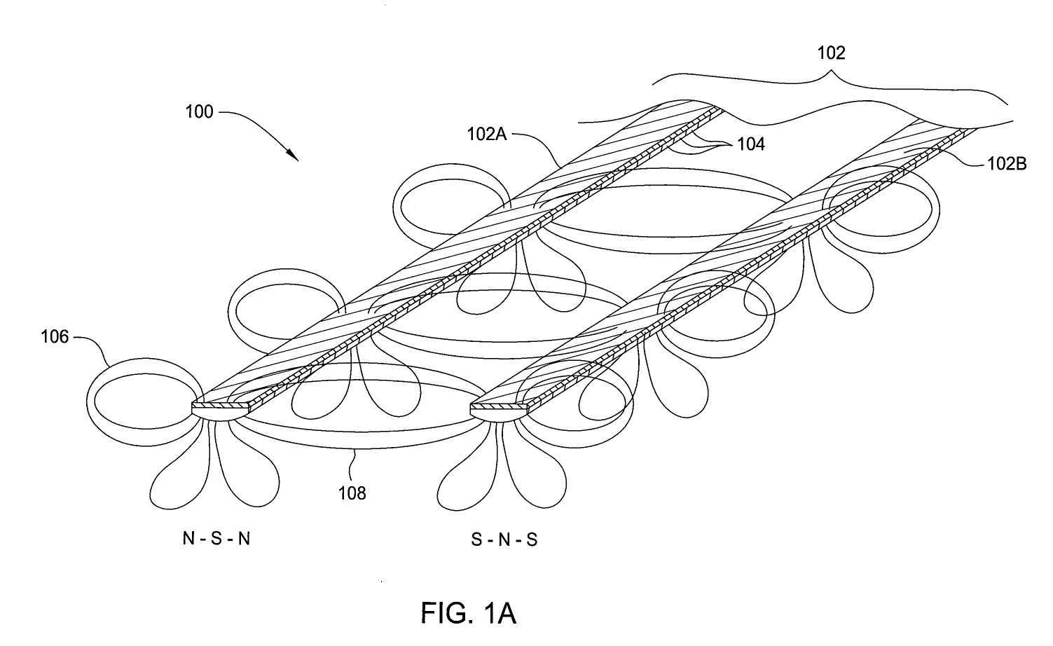

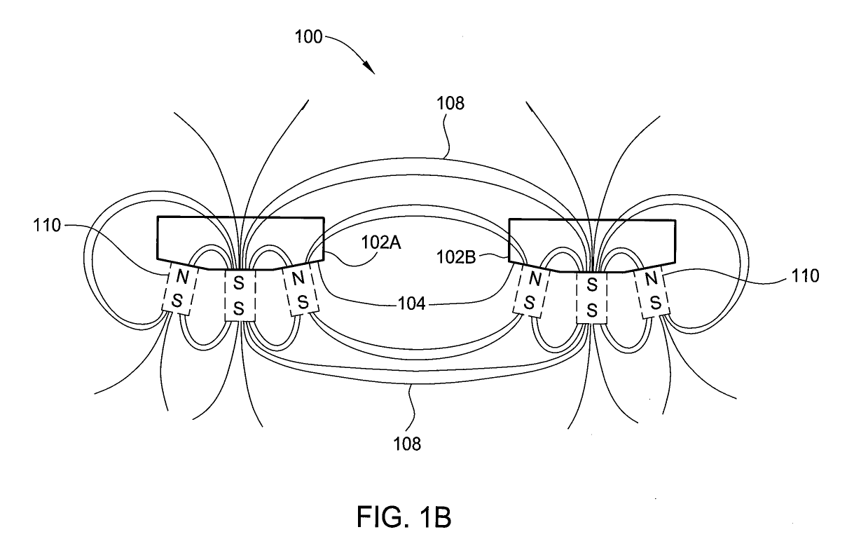

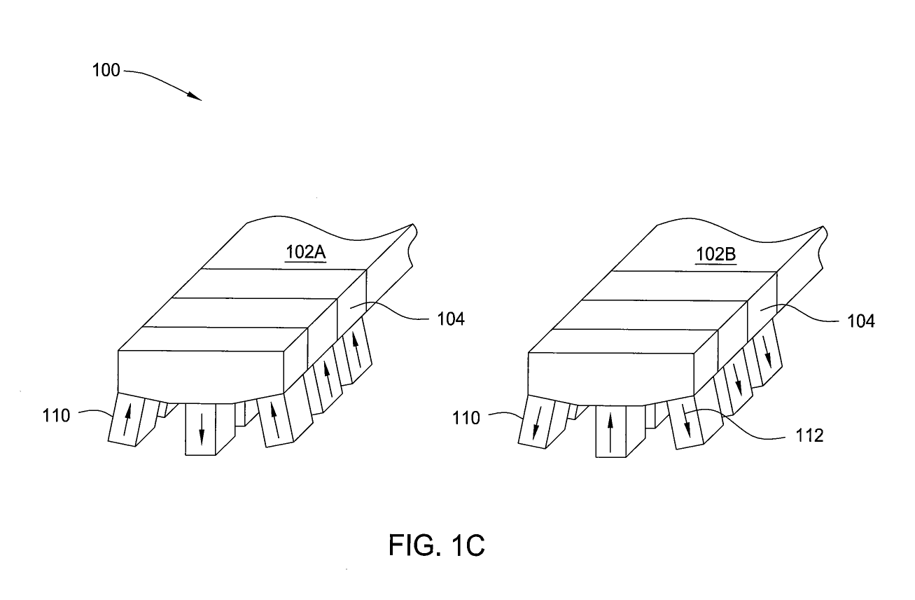

FIG. 1A is an isometric view of a magnet assembly 100 for a sputtering chamber according to one embodiment. The magnet assembly 100 comprises a plurality of magnet clusters 102. In the embodiment of FIG. 1A, two magnet clusters 102A and 102B are shown, but more than two magnet clusters may be used. Each of the magnet clusters 102A and 102B comprises a plurality of magnet units 104 oriented along an axis of each cluster. Each cluster thus resembles a bar in shape, in the embodiment of FIG. 1A. In some embodiments, the magnet clusters 102A/B are disposed in a linear configuration. The orientation of the magnet units 104 gives rise to a magnetic field 106 characteristic of the magnet cluster. The magnet clusters 102A and 102B are generally oriented such that their magnetic fields 106 couple, with resulting magnetic field lines 108 that traverse the space between the magnet clusters 102A and 102B. In some embodiments, each magnet unit 104 has a magnetic polarity, and is aligned such that its polarity is opposite that of its immediate neighbors.

During a typical sputtering process using a magnet assembly such as the magnet assembly 100 of FIG. 1A, an electric field ionizes a sputtering gas, such as argon or helium, into ions and electrons. The ions and electrons are influenced by the magnetic field lines 108 emanating from the magnet assembly. The ions collide with the sputtering target surrounding each magnet cluster, while the electrons travel along the magnetic field lines colliding with neutral species and ionizing them. The magnetic field lines thus trap electrons into “race tracks” that follow the magnetic field lines, enhancing ionization and sputtering performance. Having magnetic field lines that are coupled between magnet clusters holds the electrons to trajectories generally near the sputtering targets and enhances production of ions. Coupled magnetic fields also reduce current flows near the substrate surface, which improves deposition uniformity.

FIG. 1B is a detailed cross-sectional view of the magnet assembly 100 of FIG. 1A. The cross-sectional view of the magnet clusters 102A and 102B reveals the structure of the individual magnet units 104 that make up the magnet clusters 102A and 102B of the embodiment of FIG. 1A. Each magnet unit 104 comprises one or more magnets 110 arranged with complementary polarity. The magnets 110 may have any convenient shape, such as bar magnets, and are generally arranged such that the south pole of one is adjacent the north poles of neighboring magnets. The magnetic field formed by such an arrangement helps maintain an electromagnetic envelope for electrons near the sputtering targets, with minimal peripheral propulsion toward chamber walls or substrates. This convergent magnetic field prevents electrons from travelling toward the substrate surface and forming electric currents through the plasma near the substrate surface. Such electric currents can cause fluctuations in composition of gases near the substrate surface, resulting in non-uniform deposition.

FIG. 1C is a schematic top view of a portion of the magnet assembly 100 of FIG. 1A. The magnet units 104 are aligned along an axis of each magnet cluster 102A and 102B, with individual magnets 110 populating the magnet units 104. The polarities of the individual magnets 110 are indicated by arrows 112. In the arrangement of FIG. 1C the polarity of a magnet 110 is arranged opposite that of adjacent magnets in the same magnet unit. The polarity of magnets at the periphery of each magnet cluster 102A and 102B are opposite that of the corresponding magnet in the other cluster. This arrangement ensures that the overall polarity of the aggregate magnetic field produced by each magnet cluster 102A and 102B is opposite that of adjacent magnet clusters. In some embodiments, the magnets 110 may be rectangular in shape, such as bar-shaped. In other embodiments, the magnets 110 may be rod-shaped, with a substantially circular cross-section, or any other convenient shape. The magnets 110 may be any arbitrary shape, but will generally have a magnetic polarity that can be oriented with the position of each magnet. In FIG. 1C, the magnet units in a magnet cluster are arranged with the same polarity, each magnet unit oriented the same as adjacent magnet units in the cluster. In other embodiments, magnet units may be arranged with polarity opposite that of adjacent magnet units in the cluster.

Some embodiments of the invention provide a method of forming a magnetic field for a large-area substrate sputtering process. Magnets are generally disposed in an array near one or more sputtering targets above a substrate support in a large-area sputtering chamber. The magnet array generally covers most of the sputtering area with a magnetic field comprising the coupled magnetic fields of the individual magnets. The magnets are aligned such that their individual polarities complement and couple.

The coupled magnetic field blocks formation of electric currents near the surface of the substrate being sputtered. Electrons are held near the sputtering target by convergent magnetic field lines. Suppression of currents near the substrate surface minimizes disturbance to the uniformity of deposition such currents cause. Confinement of electrons to the space around the sputtering targets also enhances electron density and deposition rate.

In some embodiments, magnets may be arranged in a rectilinear array above a planar sputtering target. In one embodiment, each magnet will be aligned such that its polarity is opposite that of adjacent magnets on all sides. In another embodiment of a rectilinear array, each magnet may be aligned such that its polarity is opposite that of adjacent magnets in the same row, but the same as adjacent magnets in the same column. The magnets may be any convenient shape, such as rectangular, bar-shaped, or rod-shaped, and may be arranged in clusters. The magnet clusters will generally acquire an overall magnetic polarity by virtue of the individual magnets. The clusters will generally be arranged such that their magnetic polarities complement each other. In one embodiment, each magnetic cluster will be aligned such that its magnetic polarity is opposite that of magnet clusters on all sides. In another embodiment, each magnetic cluster may be aligned such that its polarity is opposite that of adjacent magnet clusters in the same row, but the same as adjacent magnet clusters in the same column. Arranging the magnets and magnetic clusters such that their polarities are complimentary creates a magnetic field around the magnet array that supports a high electron density during sputtering. Electrons formed when atoms and molecules in the sputtering gas are ionized follow the magnetic field lines, which when coupled from magnet to magnet recurve toward the sputtering target. Fewer electrons escape along divergent field lines, and electron density is higher in the plasma.

In one embodiment, individual magnets may be disposed on a grid near a sputtering target disposed between the magnets and the substrate support. The grid may be rectilinear, such that lines connecting the centroid of one magnet with the centroids of adjacent magnets form right angles, or the grid may have other organizing geometries. For example, individual magnets may be disposed on a grid with a circular pattern, with the circles being concentric rings or repeating units. As another example, the individual magnets may be disposed on a linear grid wherein lines connecting the centroids of adjacent magnets form angles that are acute or obtuse.

In some embodiments, the magnets may be clustered in a plurality of magnet bars, comprising at least a first magnet bar and a second magnet bar adjacent to the first magnet bar, wherein the magnet bars are disposed within cylinder-like sputtering targets. The magnet bars and sputtering targets are aligned such that the polarity of one magnet bar is opposite that of adjacent magnet bars. Thus, the first magnet bar is aligned such that its polarity is opposite that of the second magnet bar.

In other embodiment, the magnets may be grouped in ring formations. In one embodiment individual magnets may be grouped in ring formations, and the ring groups of magnets repeated over a planar sputtering target. In another embodiment, individual magnets may be grouped in a concentric ring formation over a planar sputtering target. In other embodiments, the sputtering target may be curved according to any convenient shape.

In most embodiments, each individual magnet is arranged such that its polarity is opposite that of adjacent magnets. In embodiments wherein magnets are grouped or clustered, each group or cluster is aligned with adjacent groups or clusters such that the overall polarity of each group or cluster is opposite that of adjacent groups or clusters. In some embodiments, some subsets or subgroups of magnets may be aligned in the same direction.

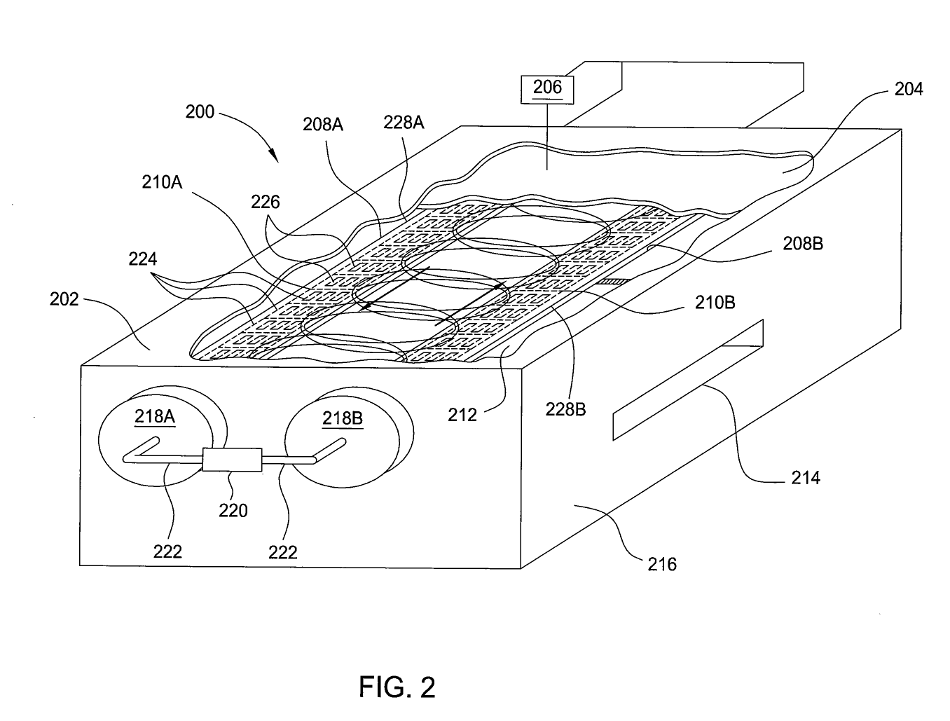

FIG. 2 is a perspective view of a large-area deposition chamber 200 according to one embodiment of the invention. The deposition chamber 200 comprises a roof 202, which is shown cut away in FIG. 2 to display the interior of the chamber 200. The chamber 200 also comprises a plate 204, also shown cut away. The plate 204 is coupled to a power source 206 for generating an electric field inside the chamber 200. The power source 206 may be a power supply, such as a DC power supply or an RF power supply, and is also coupled to sputtering target assemblies 208A and 208B disposed inside the chamber 200 for generating an electric potential between the target assemblies 208A/B and the plate 204. The embodiment of FIG. 2 shows two sputtering target assemblies disposed in the chamber 200 for purposes of explanation, but more than two may be used.

The sputtering target assemblies 208A and 208B are cylinder-like members that have interior spaces. Each sputtering target assembly 208A and 208B comprises a cylinder-like target 228A/B with a magnet assembly 210A and 210B disposed therein. The magnet assemblies 210A/B provide magnetic fields for shaping the paths of charged particles in the plasma generated by the electric field. Ions are generally attracted to the target assemblies 208A/B, colliding therewith and dislodging neutrally charged particles of sputtered material, which fall to a substrate disposed on a substrate support 212, just visible near the bottom of the chamber 200. A substrate may be disposed on the substrate support 212 through opening 214 in a sidewall 216 of the chamber 200. The opening 214 is generally large enough to admit a substrate with a carrying mechanism, allow the carrying mechanism to deposit the substrate on the substrate support 212, and then withdraw through the opening 214. The opening 214 is also generally configured to provide a vacuum seal when closed.

The chamber 200 also comprises thermal control units 218A/B for controlling temperature of the sputtering target assemblies 208A/B. A thermal control source 220 provides a thermal control fluid to each thermal control unit 218A/B through piping 222. The fluid passes through the thermal control units 218A/B and into the interior space of each sputtering target assembly 208A/B. The fluid flows through the interior space of each sputtering target assembly 208A/B and around each of the magnet assemblies 210A/B, absorbing heat from, or transmitting heat to, the interior surface of each sputtering target assembly 208A/B to maintain the sputtering target assemblies 208A/B at a target temperature. The thermal control fluid may be a cooling fluid or a heating fluid, and may be a liquid or a gas. In some embodiments, the thermal control fluid is water. The thermal control fluid is usually selected to avoid reaction with the sputtering target assemblies 208A/B or any materials in the magnet assemblies 210A/B.

Each magnet assembly 210A/B comprises one or more magnet units 224 disposed along a major axis of the magnet assembly. In some embodiments, the magnet units are disposed in a linear configuration along the major axis of the magnet assembly. Each magnet unit 224 comprises one or more magnets 226 arranged to provide a magnetic field for enhancing the sputtering process. Each of the magnets 226 has a polarity, and each magnet 226 is generally aligned such that its magnetic polarity is opposite that of adjacent magnets. The magnetic fields of the individual magnets combine in a complementary way to form a magnetic field characteristic of each magnet unit 224. Each magnet unit 224 thus has a magnetic polarity arising from the combined magnetic polarities of its constituent magnets. In one embodiment, each magnet unit 224 is aligned such that its polarity is opposite that of adjacent magnet units, creating a complementary magnetic field characteristic of the magnet assembly 210A/B. In another embodiment, each magnet unit 224 is aligned such that its polarity is the same as that of adjacent magnet units. Each magnet assembly 210A/B is, in turn, generally aligned such that its magnetic polarity is opposite that of adjacent magnet assemblies, creating a complementary magnetic field between the assemblies. The complementary magnetic field formed by aligned magnets comprises magnetic field lines that direct electrons toward the sputtering targets, rather than channeling them toward the substrate support. Such an arrangement enhances sputtering by maximizing electron density of the plasma, and minimizes plasma damage to the substrate.

In alternate embodiments, the magnet assemblies 210A/B may comprise a plurality of magnets such as the magnets 226 in a configuration that does not resolve into magnet units. For example, the magnets 226 depicted in FIG. 2 may be staggered, such that a line drawn between two magnets in one row or column bisects a magnet in an adjacent row or column. In such an embodiment, each magnet may be oriented such that its polarity is opposite that of adjacent magnets in the same column, or all magnets in a column may be oriented with the same polarity, and each magnet column is oriented with polarity opposite that of adjacent magnet columns.

The chamber 200 is described as an enclosed chamber into which a substrate is disposed through the opening 214. In alternate embodiments, however, the chamber floor may be effectively replaced by a moving conveyor that positions successive substrates in the sputtering zone. In such an embodiment, instead of an opening 214 in the sidewall 216, a recess may be provided in a lower portion of the sidewall 216 through which the moving conveyor travels.

In another embodiment, the individual magnets 226 are arranged in an array near one or more sputtering targets in a sputtering reactor. The individual magnets may be arranged in a rectilinear grid, with each magnet aligned such that its polarity is opposite that of adjacent magnets. Such a magnet array may be deployed above a planar sputtering target in a chamber such as chamber 200. In another embodiment, the individual magnets may be grouped into clusters with coupled magnetic fields. These clusters may be of any convenient shape, such as square, rectangular, or circular. The magnets may be aligned as described above, with polarities opposite those of adjacent magnets to couple the magnetic fields. The magnetic clusters may be positioned above a planar sputtering target, or multiple targets approximating the size of each cluster or groups of clusters may be used.

In some embodiments, magnet units or clusters comprising a plurality of individual magnets may be grouped into magnet assemblies, wherein the magnet units or clusters are aligned such that their polarities are the same as those of adjacent magnet units or clusters. In such embodiments, a complementary magnetic field may be established between magnet assemblies by aligning each magnet assembly such that its polarity is opposite that of adjacent magnet assemblies.

In other embodiments, magnets such as the magnets 226 may be arranged in ring formations adjacent one or more sputtering targets. The ring formations may be nested. The magnets will be aligned such that each magnet's polarity complements that of adjacent magnets, so that their magnetic fields couple. Each ring of magnets will therefore have a magnetic field that alternates in polarity at regular intervals around the circumference of the ring. For nested ring formations, each ring will generally be arranged such that its magnetic field alternates in a way that complements the alternating magnetic fields of a surrounding magnet ring, and also of any magnet ring it surrounds. For non-nested ring formations, each magnet ring will be aligned such that its alternating magnetic field complements that of adjacent magnet rings.

In some embodiments, the behavior of the plasma near the substrate surface may be influenced by the choice of materials for hardware near the substrate. In one embodiment, the substrate support may be formed from insulating material. The insulating material will limit coupling of plasma current through the hardware, and may allow for different charging potentials along surfaces. In some embodiments, the substrate support may be aluminum coated with an insulating material. The materials chosen will generally be robust under processing and cleaning conditions, and be able to withstand maintenance. Ceramic or glass may be used for some embodiments. In other embodiments, an insulating polymer coating may suffice.

In an example, SnO₂ was reactively sputtered from a plasma using two Sn targets. The targets were maintained about 5 inches from a substrate disposed on a substrate support in the sputtering chamber. A sputtering gas composed of Argon gas was provided to the sputtering chamber, and total gas pressure maintained at 3 mTorr. Sputtering power of 50 kW AC was applied to the targets and the electrode. The two cylinder-like targets each had a bar-like linear magnet array disposed inside, each magnet array having a plurality of magnets arranged in a linear fashion along the major axis of the magnet bar. The magnets in each assembly were grouped into three columns with a staggered relationship such that a line drawn between two magnets in the same column bisected a magnet in an adjacent column. Each magnet was aligned such that its polarity was the same as adjacent magnets in the same column, but opposite that of magnets in adjacent columns.

In the first example, the two magnet arrays were disposed with overall polarity in the same direction. In the second example, the two magnet arrays were disposed with overall polarity in the opposite direction. Deviation from average thickness of the deposited film at the edge of the substrate was reduced from about 2% to about 1% or less for a large-area substrate 100 inches in width. Edge thickness uniformity was similarly improved for two 38 inch panels simultaneously processed.

While the foregoing is directed to embodiments of the invention, other and further embodiments of the invention may be devised without departing from the basic scope thereof.

What is claimed is:

1. A magnetic assembly for a large-area sputtering apparatus, comprising:
a plurality of magnet clusters, each cluster comprising a plurality of magnet units oriented along a major axis of the cluster, each cluster adjacent to at least one other cluster, and each cluster oriented such that its magnetic field couples with the magnetic fields of adjacent clusters.

2. The magnetic assembly of claim 1, wherein each cluster is oriented such that the polarity of its magnetic field is opposite the polarities of adjacent clusters.

3. The magnetic assembly of claim 2, wherein the plurality of magnet units is oriented in a linear configuration in each magnet cluster.

4. The magnetic assembly of claim 3, wherein each magnet unit is oriented such that its magnetic field is coupled with the magnetic fields of adjacent magnet units.

5. The magnetic assembly of claim 3, wherein each magnet unit is oriented such that the polarity of its magnetic field is the same as the polarities of adjacent magnet units.

6. The magnetic assembly of claim 3, wherein each magnet unit is oriented such that the polarity of its magnetic field is opposite the polarities of adjacent magnet units.

7. The magnetic assembly of claim 1, wherein the major axis of each magnet cluster is oriented substantially parallel to the major axis of each adjacent magnet clusters, and each cluster's plurality of magnet units is aligned linearly along the major axis of the cluster.

8. The magnetic assembly of claim 7, wherein the magnetic polarity of each magnet unit is aligned opposite that of neighboring magnet units.

9. The magnetic assembly of claim 7, wherein the magnetic polarity of each magnet unit is aligned in the same direction as that of neighboring magnet units.

10. A method of forming a film on a large-area substrate by physical vapor deposition, comprising:
aligning a plurality of oriented magnetic clusters, each cluster having a magnetic polarity, inside one or more sputtering targets adjacent to the substrate such that the magnetic fields of the clusters couple.

11. The method of claim 10, wherein each magnetic cluster is disposed inside a first sputtering target adjacent at least one other magnetic cluster disposed inside a second sputtering target.

12. The method of claim 11, wherein each magnetic cluster comprises a plurality of magnetic units aligned along a major axis of the magnetic cluster.

13. The method of claim 12, wherein each magnetic unit of a magnetic cluster has a polarity aligned in the same direction as the other magnetic units of the same magnetic cluster.

14. The method of claim 12, wherein each magnetic unit of a magnetic cluster has a polarity aligned in the opposite direction as adjacent magnetic units of the same magnetic cluster.

15. The method of claim 10, further comprising disposing the substrate on an insulating surface of a substrate support.

16. The method of claim 15, wherein the substrate support is coated with an insulating material.

17. An apparatus for depositing a film on a large-area substrate by physical vapor deposition, comprising:
a substrate support having an insulating surface; and
a plurality of sputtering target assemblies opposite the substrate support, each sputtering target assembly comprising:
a cylinder-like target; and
a magnet assembly inside the cylinder-like target, wherein each magnet assembly comprises a plurality of magnet units arranged in a linear orientation along an axis of the magnet assembly, each magnet unit comprising a plurality of magnets, each magnet in a magnet unit having a magnetic polarity aligned opposite that of adjacent magnets in the magnet unit, each magnet unit having a polarity aligned opposite that of adjacent magnet units, and each magnet assembly having a polarity aligned opposite that of adjacent magnet assemblies.

18. The apparatus of claim 17, wherein the substrate support is formed from an insulating material.

19. The apparatus of claim 18, wherein the sputtering targets are spaced apart to form a coupled magnetic field between the sputtering targets.
